(19) United States
(12) Patent Application Publication
(10) Pub. No.: US 2019/0302203 A1
(43) Pub. Date: Oct. 3, 2019

(54) MRI Rectal Tube

(71) Applicant: Robert Gardner, Carmel, CA (US)

(72) Inventor: Robert William Gardner, Carmel, CA (US)

(73) Assignee: Robert Gardner, Carmel, CA (US)

(21) Appl. No.: 16/423,010

(22) Filed: May 26, 2019

(51) Int. Cl. G01R 33/38; G01R 33/28

(52) U.S. Cl. CPC G01R 33/38; G01R 33/3642; G01R 33/285

(57) ABSTRACT

This is a unique medical device that will be used to optimize MRI imaging in the low pelvic region by displacing gas and fecal material from the rectum and sigmoid colon. The quality of MRI imaging depends very much on the homogeneity of the magnetic field within body tissues. Abrupt changes in tissue interface (air adjacent to solid tissue or fluid) creates field inhomogeneities that can adversely affect MRI quality.

This novel device is designed to minimize the inhomogeneities that are inherent in the pelvis during MRI examinations. This device is specifically designed to optimize the MR imaging environment in the low pelvic region. It is not a receiver coil or an immobilization device. This invention addresses the common problem of field inhomogeneity in MRI imaging due to rectal gas and fecal material.

The invention described herein is designed to address a common problem in MR imaging of the low pelvic region. Quality MR images require a very homogeneous magnetic field and artifacts are created when magnetic field homogeneity is not optimal. This can severely affect overall image quality and therefore diagnostic ability of the MRI scan. The most common imaging artifacts that occur in the pelvis are due to gas and fecal material in the rectum and colon. The air/tissue interfaces create magnetic field inhomogeneities. By inserting the described rectal tube and inflating/filling the balloon with saline or other fluid, the gas/air in the rectum and colon are displaced and a more homogeneous magnetic field is created. This will vastly improve the quality of images in the region and improve diagnostic power.

The internal lumen of the catheter itself is separate from the inflatable balloon. This internal lumen can be filled with semi-solid/gelatinous material with imaging properties similar to common malignancies. This can therefore serve as an internal control to which patients' tissues can be compared.

### BRIEF DESCRIPTION OF DRAWINGS

FIG. 1: This is a profile view of the rectal tube and balloon in its deflated and insertable state. The tube contains an injection side port which communicates with the inner lumen of the balloon for inflation/filling with saline or other homogeneous fluid. The end of open end of the catheter can be filled with gelatinous material with defined MRI diffusion properties.

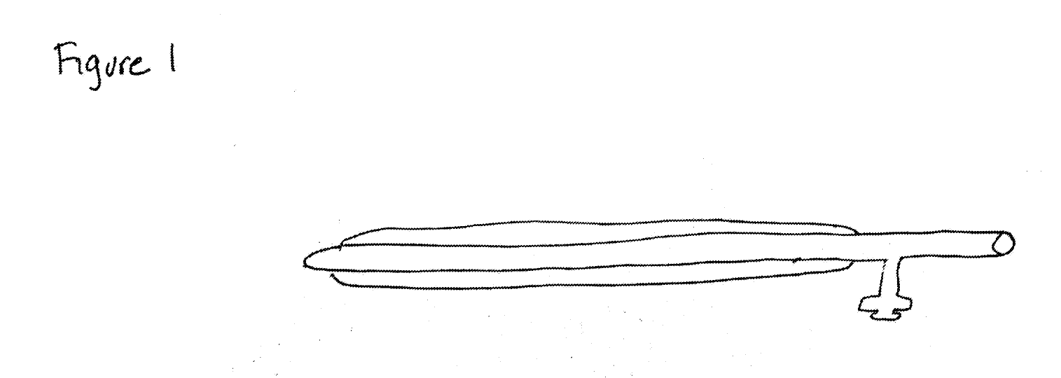

FIG. 2: This is a profile view with the balloon in its inflated state. The complaint balloon is shown conforming to the irregular contour of the recto-sigmoid colon. This shape will conform to the contour of the rectum and colon that will be different in every patient. In the inflated state, gas and fecal material is displaced from the MRI imagine region of interest creating a more homogenous magnetic field. This improves image quality and reduces common imaging artifacts created by inhomogeneous air/tissue interfaces.

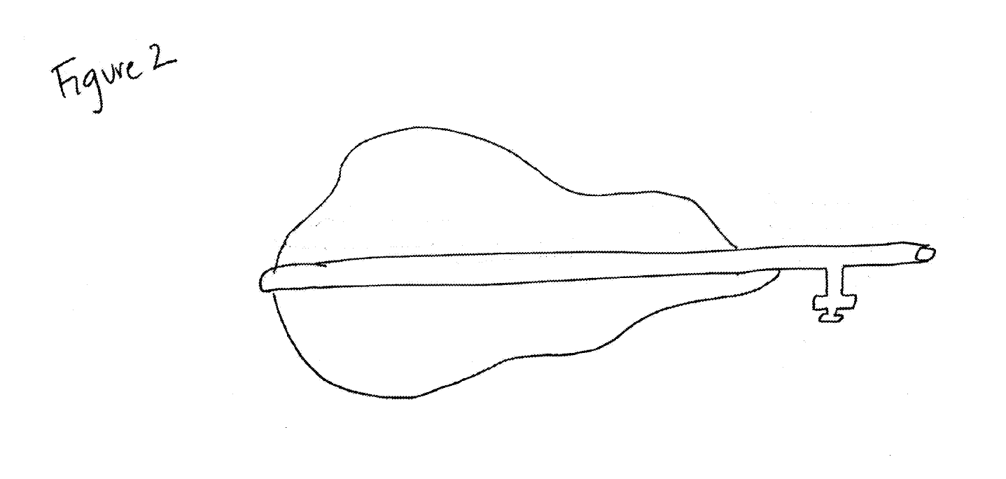

1. A large volume inflatable, low pressure, compliant rectal balloon,
a. The balloon will communicate with the self-sealing injection port so that the injection port lumen communicates the balloon.
b. The balloon can be filled with saline or other fluid.
c. The fluid filled balloon will displace gas and/or fecal material from the rectum and colon to create an optimized magnetic resonance imaging environment.

2. The internal lumen of the shaft can optionally serve as an internal control. (optional)
a. The internal lumen of the semi-stiff shaft can be filled with a semi-solid gel that mimics imaging characteristics of common malignancies.
b. The internal lumen therefore acts as a reference point for detecting abnormalities in tissues that should be scrutinized for possible cancer.
